(19) United States
(12) Patent Application Publication
(10) Pub. No.: US 2026/0342336 A1
(43) Pub. Date: Oct. 29, 2026

(54) CHANNEL DRIVER AND TRANSMISSION DRIVER INCLUDING THEREOF

(71) Applicant: SAMSUNG ELECTRONICS CO., LTD., Suwon-si (KR)

(72) Inventors: Taehee YU, Suwon-si (KR); Jaehyun PARK, Suwon-si (KR); Hwanseok YEO, Suwon-si (KR); Jaewon RYU, Suwon-si (KR)

(73) Assignee: SAMSUNG ELECTRONICS CO., LTD., Suwon-si (KR)

(21) Appl. No.: 19/395,814

(22) Filed: Nov. 20, 2025

(30) Foreign Application Priority Data
Apr. 29, 2025 (KR) 10-2025-0056720

(51) Int. Cl. H03K 19/00; H03K 19/0185

(52) U.S. Cl. CPC H03K 19/0005; H03K 19/018514; H03K 19/018585

(57) ABSTRACT

A transmission driver including a channel driver and a driver control circuit. The channel driver includes a plurality of slice circuits, and the driver control circuit controls the channel driver by adjusting a pull-up path resistance of the channel driver based on a number of activated slice circuits among the plurality of slice circuits, and adjust a pull-down path resistance of the channel driver based on a pull-down variable resistance circuit in each of the plurality of slice circuits.

### CROSS-REFERENCE TO RELATED APPLICATION

This application claims priority to and the benefit of Korean Patent Application No. 10-2025-0056720 filed with the Korean Patent Office on Apr. 29, 2025, the entire contents of which are incorporated herein by reference.

### BACKGROUND

### 1. Field

The disclosure relates to a semiconductor communication system. More specifically, the disclosure relates to a channel driver controlling channel voltage and a transmission driver including the same.

### 2. Description of the Related Art

A communication system may include a transmission driver and a receiver driver. The transmitting driver may transmit data to the receiver driver in the form of differential voltage. For example, a transmission driver may include two channel drivers respectively controlling two channels.

The transmission driver may operate in various operation modes depending on various parameters, such as, communication speed and power consumption required for the communication system. However, if the transmission driver is implemented to operate in various operation modes, an operating efficiency may be reduced compared to a case where the transmission driver is implemented to operate in only one operation mode.

### SUMMARY

The disclosure has been made in consideration of the problems described above, and provides a channel driver implemented to operate in various operation modes and a transmission driver including the same. However, the disclosure is not limited thereto, and as such, the embodiments of the disclosure may address the above described problems and/or other problems.

According to an aspect of the disclosure, there is provided a channel driver including: a first driver input node configured to receive a first channel input data; a first driver output node connected to a channel output pad; and a first plurality of slice circuits connected in parallel between the first driver input node and the first driver output node, wherein a first slice circuit, among the first plurality of slice circuits, includes: a first pulling circuit connected between the first driver input node and a first common node; and a first variable common resistance circuit connected between the first common node and the first driver output node, the first variable common resistance circuit configured to operate based on a first common resistance adjustment signal.

According to another aspect of the disclosure, there is provided a transmission driver including: a first driver circuit including a first driver output node connected to a first channel output pad; a second driver circuit including a second driver output node connected to the first channel output pad; and a driver control circuit configured to: activate the first driver circuit during a first time period in a case in which the first driver circuit and the second driver circuit operate in a non-return to zero (NRZ) mode, and activate the first driver circuit and the second driver circuit during a second time period in a case in which the first driver circuit and second driver circuit operate in a pulse amplitude modulation with 4-level (PAM-4) mode, wherein the second driver output node is configured to be electrically floated during the first time period.

According to another aspect of the disclosure, there is provided a transmission driver, including: a channel driver including a plurality of slice circuits; and a driver control circuit configured to control the channel driver, wherein the driver control circuit is configured to: adjust a pull-up path resistance of the channel driver based on a number of activated slice circuits among the plurality of slice circuits; and adjust a pull-down path resistance of the channel driver further based on a pull-down variable resistance circuit in each of the plurality of slice circuits.

### BRIEF DESCRIPTION OF DRAWINGS

The and other aspects, features, and advantages of the embodiments of the disclosure will be more clearly understood from the following detailed description, taken in conjunction with the accompanying drawings, in which:

FIG. 1 is a block diagram showing a communication system according to an embodiment of the disclosure.

FIG. 2 is a block diagram showing the structure of the transmission driver of FIG. 1 in more detail.

FIG. 3 is a graph showing the difference voltage in an example case in which the transmission driver operates in a non-return to zero (NRZ) mode.

FIG. 4 is a graph showing the difference voltage in an example case in which the transmission driver operates in PAM-4 mode.

FIG. 5 is an equivalent circuit diagram for the first channel driver of FIG. 2.

FIG. 6 is a circuit diagram exemplarily showing the configuration of one slice circuit included in the first driver circuit.

FIG. 7 is a circuit diagram exemplarily showing the configuration of one slice circuit included in the second driver circuit.

FIG. 8 is a circuit diagram exemplarily showing the configuration of the pull-down variable resistance circuit of FIGS. 6 and 7.

FIGS. 9 and 10 are drawings showing the specific operation method of the first channel driver.

FIG. 11 is a circuit diagram exemplarily showing the configuration of one slice circuit included in the first driver circuit.

FIG. 12 is a circuit diagram exemplarily showing the configuration of one slice circuit included in the first driver circuit.

FIG. 13 is a block diagram showing an electronic communication system according to an embodiment.

### DETAILED DESCRIPTION

Hereinafter, various embodiments will be described in detail and clearly to such an extent that an ordinary one in the art easily implements the disclosure. Specific details such as detailed components and structures are merely provided to assist the overall understanding of the various embodiments. Therefore, it should be apparent to those skilled in the art that various changes and modifications of the embodiments described herein may be made without departing from the scope and spirit of the disclosure. Moreover, descriptions of well-known functions and structures are omitted for clarity and brevity. In the following drawings or in the detailed description, configurations may be connected with any other components except for components illustrated in a drawing or described in the detailed description. The terms described below are terms defined in consideration of the functions of the disclosure and are not limited to a specific function. The definitions of the terms should be determined based on the contents throughout the specification.

Components that are described in the detailed description with reference to the terms “driver”, “block”, etc. will be implemented with software, hardware, or a combination thereof. For example, the software may be a machine code, firmware, an embedded code, and application software. For example, the hardware may include an electrical circuit, an electronic circuit, a processor, a computer, integrated circuit cores, a pressure sensor, a microelectromechanical system (MEMS), a passive element, or a combination thereof.

A singular expression may include a plural expression, unless the context clearly indicates that it is singular. In addition, when a portion is said to “comprise,” “include,” “provide,” or “have” a component, this may mean that other components may be additionally included, rather than excluding other components, unless otherwise specifically stated.

With respect to operations constituting a method, when an order is explicitly stated or when there is no other description, the operations constituting the method may be performed in an appropriate order. It may not be necessarily limited to an order of the operations described. All examples or illustrative terms may be used only to explain technical ideas, and the scope is not limited by the examples or illustrative terms, unless otherwise specified by the claims.

In the following descriptions, when ordinal numerals such as “first” and “second” are attached for explanation, they may be used for convenience and do not specify any order, unless specifically stated.

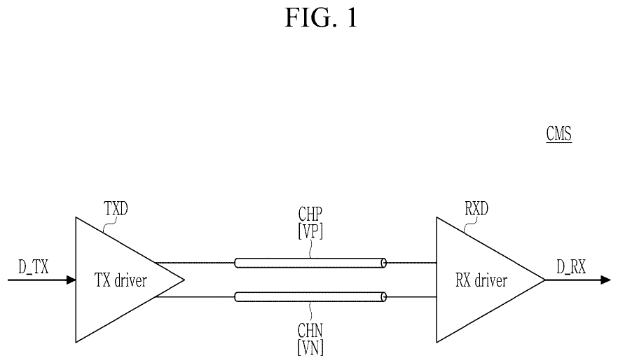

FIG. 1 is a block diagram showing a communication system according to an embodiment of the disclosure. Referring to FIG. 1, a communication system CMS may include a transmission driver TXD and a receiver driver RXD. Each of the transmission driver TXD and the receiver driver RXD may be connected to a first channel CHP and a second channel CHN. A voltage level of the first channel CHP may be referred to as a first channel voltage VP, and a voltage level of the second channel CHN may be referred to as a second channel voltage VN.

In an embodiment, the communication system CMS may be used to implement various types of communication interfaces. For example, the communication system CMS may be used to implement various types of communication interfaces such as M-PHY, Peripheral Component Interconnect Express PCIe, etc. However, the scope of the disclosure is not limited thereto.

The transmission driver TXD may receive transmission data D_TX. The transmission driver TXD may control the first channel CHP and the second channel CHN based on the transmission data D_TX. For example, the transmission driver TXD may adjust the difference between the first channel voltage VP and the second channel voltage VN based on the transmission data D_TX. That is, the transmitting driver TXD may provide a differential voltage corresponding to the transmission data D_TX to the receiver driver RXD based on the first channel CHP and the second channel CHN.

The receiver driver RXD may generate reception data D_RX based on the differential voltage provided from the first channel CHP and the second channel CHN. For example, the receiver driver RXD may generate (e.g., decode) reception data D_RX based on a difference between the first channel voltage VP and the second channel voltage VN.

In an embodiment, the first channel CHP may be referred to as a positive channel and the second channel CHN may be referred to as a negative channel. However, the scope of the disclosure is not limited to these terms.

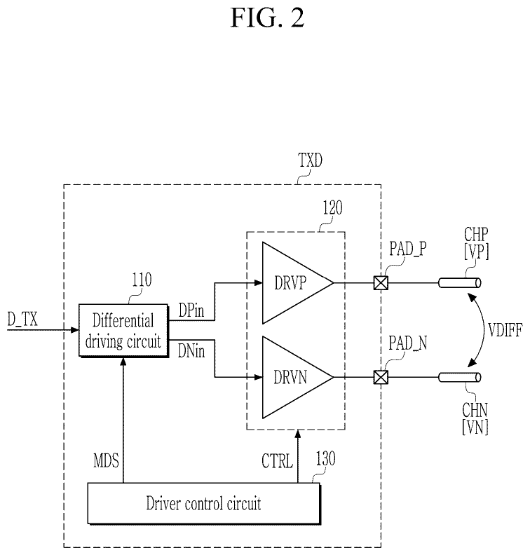

FIG. 2 is a block diagram showing the structure of the transmission driver of FIG. 1 in more detail. Referring to FIGS. 1 and 2, the transmission driver TXD may include a differential driving circuit 110, a channel driver array 120, and a driver control circuit 130.

The differential driving circuit 110 may receive the transmission data D_TX. For example, the differential driving circuit 110 may sequentially receive a plurality of bits included in the transmission data D_TX.

The differential driving circuit 110 may generate first channel input data DPin and second channel input data DNin based on the transmission data D_TX. The first channel input data DPin and the second channel input data DNin may be complementary to each other. For example, the first channel input data DPin and the second channel input data DNin may have a relationship of bit-wise complement. In other words, the second channel input data DNin may correspond to a result of flipping each bit of the first channel input data DPin. For example, the second channel input data DNin may be obtained by flipping each bit of the first channel input data DPin.

The channel driver array 120 may include a first channel driver DRVP and a second channel driver DRVN. The first channel driver DRVP may be connected to the first channel CHP. For example, the first channel driver DRVP may be connected to the first channel CHP through a first channel output pad PAD_P. The second channel driver DRVN may be connected to the second channel CHN. For example, the second channel driver DRVN may be connected to the second channel CHN through a second channel output pad PAD_N.

The first channel driver DRVP may control the first channel voltage VP based on the first channel input data DPin. The second channel driver DRVN may control the second channel voltage VN based on the second channel input data DNin. The difference between the first channel voltage VP and the second channel voltage VN may be referred to as a difference voltage VDIFF. The receiver driver RXD may generate reception data D_RX corresponding to the transmission data D_TX based on a voltage level of the difference voltage VDIFF.

In an embodiment, the configurations of the first channel driver DRVP and the second channel driver DRVN may correspond to each other. For example, the first channel driver DRVP and the second channel driver DRVN may have the same circuit configuration and may be implemented to receive complementary data from each other. However, the scope of the disclosure is not limited thereto.

In an embodiment, the first channel driver DRVP may be referred to as a positive channel driver, and the second channel driver DRVN may be referred to as a negative channel driver. However, the scope of the disclosure is not limited to these terms.

The driver control circuit 130 may control overall operations of the transmission driver TXD. The driver control circuit 130 may generate a mode selection signal MDS and various types of control signals CTRL based on a control of an external device. For example, the driver control circuit 130 may generate a mode selection signal MDS and various types of control signals CTRL in response to a control of an external device. The driver control circuit 130 may determine the operation mode of the transmission driver TXD (for example, the operation mode of each channel driver included in transmission driver TXD) as one of a non-return to zero (NRZ) mode and a pulse amplitude modulation with 4-level (PAM-4) mode based on the mode selection signal MDS and the control signals CTRL.

In an example case in which the driver control circuit 130 generates the mode selection signal MDS indicating the NRZ mode, the differential driving circuit 110 may determine the first channel input data DPin and the second channel input data DNin in 1-bit unit. That is, the differential driving circuit 110 may repeatedly perform an operation of providing 1-bit to each of the first channel driver DRVP and the second channel driver DRVN.

In an example case in which the driver control circuit 130 generates the mode selection signal MDS indicating the PAM-4 mode, the differential driving circuit 110 may determine the first channel input data DPin and the second channel input data DNin in 2-bit unit. That is, the differential driving circuit 110 may repeatedly perform an operation of providing 2-bits to each of the first channel driver DRVP and the second channel driver DRVN.

In an embodiment, sizes of a channel pull-up path resistance and a channel pull-down path resistance for each of the first channel driver DRVP and the second channel driver DRVN for stable operation of the communication system CMS may be predetermined. For example, the sizes of the channel pull-up path resistance and the channel pull-down path resistance for each of the first channel driver DRVP and the second channel driver DRVN to secure signal integrity of the difference voltage VDIFF and to minimize channel reflection may be determined in advance based on various factors such as circuit configuration within the receiver driver RXD. In this case, the driver control circuit 130 may control the sizes of the channel pull-up path resistance and the channel pull-down path resistance for each of the first channel driver DRVP and the second channel driver DRVN, based on the various types of control signals CTRL. The types of control signals CTRL and the specific manner how the channel pull-up path resistance and channel pull-down path resistance for each of the first channel driver DRVP and the second channel driver DRVN are controlled are described in more detail with reference to the drawings below.

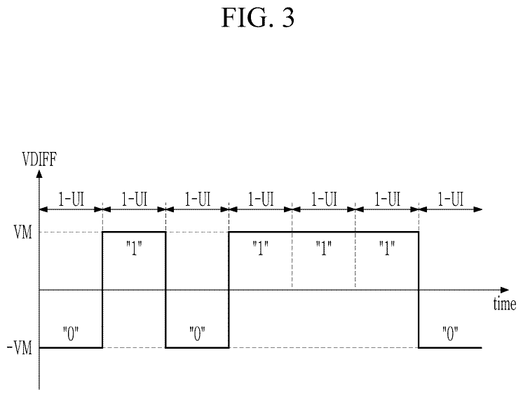

FIG. 3 is a graph showing the difference voltage in an example case in which the transmission driver operates in NRZ mode. The horizontal axis of FIG. 3 may represent time and the vertical axis may represent voltage level.

Referring to FIGS. 1 to 3, the transmission driver TXD may operate in NRZ mode. In this case, the first channel driver DRVP and the second channel driver DRVN may control the difference voltage VDIFF with two levels. For example, the first channel driver DRVP and the second channel driver DRVN may determine the voltage level of the difference voltage VDIFF as “VM” or “−VM”.

The receiver driver RXD may generate 1-bit reception data D_RX based on the voltage level of the difference voltage VDIFF for each unit interval UI. For example, the receiver driver RXD may generate reception data D_RX “1” when the voltage level of the difference voltage VDIFF is “VM” during a specific unit interval UI. For example, when the voltage level of the difference voltage VDIFF is “VM” may mean when the voltage level of the difference voltage VDIFF is closer to “VM” than “−VM”. On the other hand, the receiver driver RXD may generate reception data D_RX “0” when the voltage level of the difference voltage VDIFF is “−VM” during a specific unit interval UI. For example, when the voltage level of the difference voltage VDIFF is “−VM” may mean when the voltage level of the difference voltage VDIFF is closer to “−VM” than “VM”.

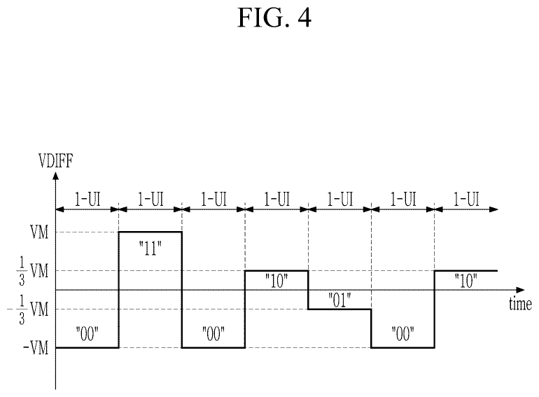

FIG. 4 is a graph showing the difference voltage in an example case in which the transmission driver operates in PAM-4 mode. The horizontal axis of FIG. 4 may represent time and the vertical axis may represent voltage level.

Referring to FIGS. 1 to 4, the transmission driver TXD may operate in PAM-4 mode. In this case, the first channel driver DRVP and the second channel driver DRVN may control the difference voltage VDIFF with four levels. For example, the first channel driver DRVP and the second channel driver DRVN may determine the voltage level of the difference voltage VDIFF as one of “VM”,

$$“ + \frac{1}{3} VM ” , “ - \frac{1}{3} VM ” ,$$

### and “−VM”.

The receiver driver RXD may generate 2-bit reception data D_RX based on the voltage level of the difference voltage VDIFF for each unit interval UI. For example, the receiver driver RXD may generate reception data D_RX “11” when the voltage level of the difference voltage VDIFF is “VM” (for example, when the voltage level of the difference voltage VDIFF is closest to “VM”) during a specific unit interval UI; may generate reception data D_RX “10” when the voltage level of the difference voltage VDIFF is

$$“ + \frac{1}{3} VM ”$$

(for example, when the voltage level of the difference voltage VDIFF is closest to

$$“ + \frac{1}{3} VM ” )$$

during a specific unit interval UI; may generate reception data D_RX “01” when the voltage level of the difference voltage VDIFF is

$$“ - \frac{1}{3} VM ”$$

(for example, when the voltage level of the difference voltage VDIFF is closest to

$$“ - \frac{1}{3} VM ” )$$

during a specific unit interval UI; and may generate the reception data D_RX “00” when the voltage level of the difference voltage VDIFF is “−VM” (for example, when the voltage level of the difference voltage VDIFF is closest to “−VM”) during a specific unit interval UI.

Referring to FIGS. 3 and 4 together, in an example case in which the transmission driver TXD operates in PAM-4 mode, comparing to a case where the transmission driver TXD operates in NRZ mode, the transmission driver TXD may transmit twice as much data to the receiver driver RXD per unit interval UI. In other words, in an example case in which the transmission driver TXD operates in PAM-4 mode, data may be transmitted with doubled speed compared to an example case in which the transmission driver TXD operates in NRZ mode.

In an example case in which the transmission driver TXD operates in NRZ mode, the data identification margin on the receiver driver RXD side may be larger than an example case in which the transmission driver TXD operates in PAM-4 mode. Therefore, in an example case in which the transmission driver TXD operates in NRZ mode, the receiver driver RXD may generate reception data D_RX more accurately than an example case in which the transmission driver TXD operates in PAM-4 mode. That is, in an example case in which the transmission driver TXD operates in NRZ mode, the communication stability of the communication system CMS may be improved compared to an example case in which the transmission driver TXD operates in PAM-4 mode.

In an embodiment, the transmission driver TXD may be implemented to switch between the PAM-4 mode and the NRZ mode. For example, the transmission driver TXD may transition from the PAM-4 mode to the NRZ mode when high communication accuracy is required, and may transition from the NRZ mode to the PAM-4 mode when high communication speed is required.

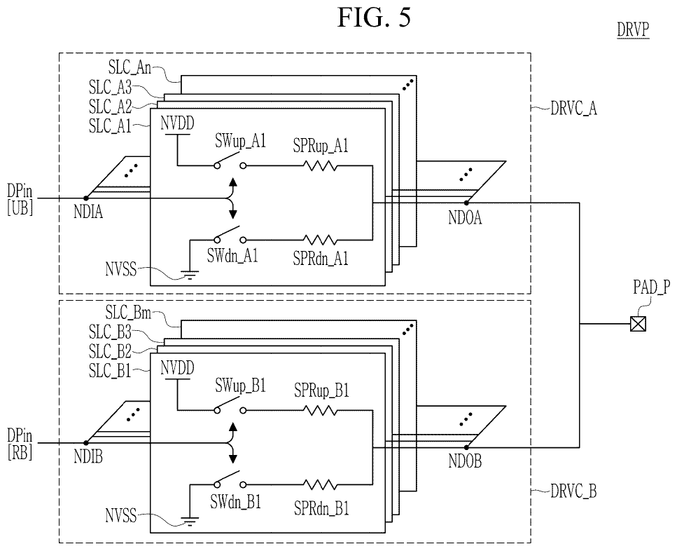

FIG. 5 is an equivalent circuit diagram for the first channel driver of FIG. 2. Referring to FIGS. 1 to 5, the first channel driver DRVP may include a first driver circuit DRVC_A and a second driver circuit DRVC_B.

The first driver circuit DRVC_A may include a first driver input node NDIA, a first driver output node NDOA, and first to n-th slice circuits SLC_A1 to SLC_An. Each of the first to n-th slice circuits SLC_A1 to SLC_An may be independently activated or deactivated based on the control signal CTRL. For example, each of the first to n-th slice circuits SLC_A1 to SLC_An may be independently activated or deactivated in response to the control signal CTRL.

The second driver circuit DRVC_B may include a second driver input node NDIB, a second driver output node NDOB, and first to m-th slice circuits SLC_B1 to SLC_Bm. Each of the first to m-th slice circuits SLC_B1 to SLC_Bm may be independently activated or deactivated based on the control signal CTRL. For example, each of the first to m-th slice circuits SLC_B1 to SLC_Bm may be independently activated or deactivated in response to the control signal CTRL.

Each of the first driver circuit DRVC_A and the second driver circuit DRVC_B may receive the first channel input data DPin. For example, the first driver circuit DRVC_A may receive an upper bit UB of the first channel input data DPin through the first driver input node NDIA, and the second driver circuit DRVC_B may receive a remaining bit RB of the first channel input data DPin through the second driver input node NDIB.

In an example case in which the transmission driver TXD operates in NRZ mode, the first channel input data DPin may be 1-bit per unit interval UI. In this case, the differential driving circuit 110 may provide such 1-bit data to the first driver circuit DRVC_A and may not provide data to the second driver circuit DRVC_B (because there is no remaining bit RB in the first channel input data DPin in NRZ mode).

In an example case in which the transmission driver TXD operates in PAM-4 mode, the differential driver circuit 110 may provide 1-bit per unit interval UI to each of the first driver circuit DRVC_A and the second driver circuit DRVC_B. For example, when the transmission driver TXD operates in PAM-4 mode, the first channel input data DPin may be 2-bits data per unit interval UI. In this case, the differential driving circuit 110 may provide an upper bit UB (e.g., a most significant bit (MSB)) of such 2-bits to the first driver circuit DRVC_A and provide a remaining bit RB (e.g., a least significant bit (LSB)) to the second driver circuit DRVC_B.

That is, when the transmission driver TXD operates in PAM-4 mode, both the first driver circuit DRVC_A and the second driver circuit DRVC_B may be activated. For example, when the transmission driver TXD operates in PAM-4 mode, one or more of the first to n-th slice circuits SLC_A1 to SLC_An and one or more of the first to m-th slice circuits SLC_B1 to SLC_Bm may be activated.

In an example case in which the transmission driver TXD operates in NRZ mode, the first driver circuit DRVC_A may be activated and the second driver circuit DRVC_B may be deactivated. For example, when the transmission driver TXD operates in NRZ mode, one or more of the first to n-th slice circuits SLC_A1 to SLC_An may be activated, and all of the first to m-th slice circuits SLC_B1 to SLC_Bm may be deactivated.

For a more concise explanation, an embodiment in which the first driver circuit DRVC_A receives the upper bit UB of the first channel input data DPin and the second driver circuit DRVC_B receives the remaining bit RB of the first channel input data DPin is representatively described below, but the scope of the disclosure is not limited thereto. For example, the first driver circuit DRVC_A may be implemented to receive the lower bits of the first channel input data DPin, and the second driver circuit DRVC_B may be implemented to receive a remaining bit of the first channel input data DPin.

In an embodiment, the first driver circuit DRVC_A may be referred to as an MSB driver circuit, and the second driver circuit DRVC_B may be referred to as an LSB driver circuit. However, the scope of the disclosure is not limited to these terms.

The first to n-th slice circuits SLC_A1 to SLC_An may be connected in parallel between the first driver input node NDIA and the first driver output node NDOA. The first to n-th slice circuits SLC_A1 to SLC_An may share the upper bit UB of the first channel input data DPin.

The first to m-th slice circuits SLC_B1 to SLC_Bm may be connected in parallel between the second driver input node NDIB and the second driver output node NDOB. The first to m-th slice circuits SLC_B1 to SLC_Bn may share the remaining bit RB of the first channel input data DPin.

Each of the first to n-th slice circuits SLC_A1 to SLC_An may be connected to a power node NVDD and a ground node NVSS. The first to n-th slice circuits SLC_A1 to SLC_An may determine a pull-up path resistance (hereinafter, referred to as a first driver pull-up path resistance DPRup_A) between the power node NVDD and the first driver output node NDOA, and a pull-down path resistance (hereinafter, referred to as a first driver pull-down path resistance DPRdn_A) between the ground node NVSS and the first driver output node NDOA.

For example, each of the first to n-th slice circuits SLC_A1 to SLC_An may be equivalently represented based on a slice pull-up path resistance SPRup_A and a pull-up path switch SWup_A connected between the power node NVDD and the first driver output node NDOA, and a slice pull-down path resistance SPRdn_A and a pull-down path switch SWdn_A connected between the ground node NVSS and the first driver output node NDOA. For example, the first slice circuit SLC_A1 may be equivalently represented based on a first slice pull-up path resistance SPRup_A1, a first pull-up path switch SWup_A1, a first pull-down path switch SWdn_A1, and a first slice pull-down path resistance SPRdn_A1. For a more concise explanation, the configuration of an equivalent circuit for the first slice circuit SLC_A1 is exemplarily described, but the scope of the disclosure is not limited thereto.

The pull-up path switch SWup_A and the pull-down path switch SWdn_A of each of the first to n-th slice circuits SLC_A1 to SLC_An may operate based on the voltage level of the first driver input node NDIA. For example, the pull-up path switch SWup_A and the pull-down path switch SWdn_A of each of activated slice circuits among the first to n-th slice circuits SLC_A1 to SLC_An may operate complementarily (e.g., only one of the two being turned on) based on the voltage level of the first driver input node NDIA. On the other hand, both the pull-up path switch SWup_A and the pull-down path switch SWdn_A of each of deactivated slice circuits among the first to n-th slice circuits SLC_A1 to SLC_An may be turned off.

In an embodiment, each of the first to n-th slice circuits SLC_A1 to SLC_An may be implemented identically to each other. For example, the slice pull-up path resistance SPRup_A of each of the first to n-th slice circuits SLC_A1 to SLC_An may have substantially same value; and the slice pull-down path resistance SPRdn_A of each of the first to n-th slice circuits SLC_A1 to SLC_An may have substantially same value. Additionally, the pull-up path switch SWup_A and the pull-down path switch SWdn_A of each of the first to n-th slice circuits SLC_A1 to SLC_An may operate in same manner. For example, all of activated slice circuits among the first to n-th slice circuits SLC_A1 to SLC_An may perform a pull-up operation (e.g., the pull-up path switch SWup_A being turned on), or all of activated slice circuits among the first to n-th slice circuits SLC_A1 to SLC_An may perform a pull-down operation (e.g., the pull-down path switch SWdn_A being turned on). However, the scope of the disclosure is not limited thereto.

The first driver pull-up path resistance DPRup_A may refer to an equivalent resistance between the power node NVDD and the first driver output node NDOA in an example case in which the activated slice circuits among the first to n-th slice circuits SLC_A1 to SLC_An perform a pull-up operation. In an example case in which all of the first to n-th slice circuits SLC_A1 to SLC_An are activated and a size of the slice pull-up path resistance SPRup_A of each of the first to n-th slice circuits SLC_A1 to SLC_An is “R1”, the first driver pull-up path resistance DPRup_A may be

$$\frac{R 1}{n} .$$

Similarly, the first driver pull-down path resistance DPRdn_A may refer to an equivalent resistance between the ground node NVSS and the first driver output node NDOA in an example case in which the activated slice circuits among the first to n-th slice circuits SLC_A1 to SLC_An perform a pull-down operation.

Therefore, the first driver pull-up path resistance DPRup_A may be determined based on the size of the slice pull-up path resistance SPRup_A and a number of activated slice circuits among the first to n-th slice circuits SLC_A1 to SLC_An. Similarly, the first driver pull-down path resistance DPRdn_A may be determined based on the size of the slice pull-down path resistance SPRdn_A included in each of the first to n-th slice circuits SLC_A1 to SLC_An and a number of activated slice circuits among the first to n-th slice circuits SLC_A1 to SLC_An.

Each of the first to m-th slice circuits SLC_B1 to SLC_Bm may be connected to the power node NVDD and the ground node NVSS. Each of the first to m-th slice circuits SLC_B1 to SLC_Bm may determine a pull-up path resistance (hereinafter, referred to as a second driver pull-up path resistance DPRup_B) between the power node NVDD and a second driver output node NDOB, and a pull-down path resistance (hereinafter, referred to as a second driver pull-down path resistance DPRdn_B) between the ground node NVSS and the second driver output node NDOB.

For example, each of the first to m-th slice circuits SLC_B1 to SLC_Bm may be equivalently represented based on a slice pull-up path resistance SPRup_B and a pull-up path switch SWup_B connected between the power node NVDD and the second driver output node NDOB, and a slice pull-down path resistance SPRdn_B and a pull-down path switch SWdn_B connected between the ground node NVSS and the second driver output node NDOB. Since the equivalent circuits of each of the first to m-th slice circuits SLC_B1 to SLC_Bm are similar to the equivalent circuits of each of the first to n-th slice circuits SLC_A1 to SLC_An described above, a detailed description is omitted.

The pull-up path switch SWup_B and the pull-down path switch SWdn_B of each of the first to m-th slice circuits SLC_B1 to SLC_Bm may operate based on a voltage level of the second driver input node NDIB. For example, the pull-up path switch SWup_B and the pull-down path switch SWdn_B of each of the activated slice circuits among the first to m-th slice circuits SLC_B1 to SLC_Bm may operate complementarily (e.g., only one of the two being turned on) based on the voltage level of the second driver input node NDIB. On the other hand, both the pull-up path switch SWup_B and the pull-down path switch SWdn_B of each of the deactivated slice circuits among the first to m-th slice circuits SLC_B1 to SLC_Bm may be turned off.

The second driver pull-up path resistance DPRup_B may refer to an equivalent resistance between the power node NVDD and the second driver output node NDOB in an example case in which activated slice circuits among the first to m-th slice circuits SLC_B1 to SLC_Bm perform a pull-up operation. The second driver pull-down path resistance DPRdn_B may refer to an equivalent resistance between the ground node NVSS and the second driver output node NDOB in an example case in which activated slice circuits among the first to m-th slice circuits SLC_B1 to SLC_Bm perform a pull-down operation. The specific method in which the second driver pull-up path resistance DPRup_B and the second driver pull-down path resistance DPRdn_B are determined is similar to that described above with reference to the first driver circuit DRVC_A, so a detailed description is omitted.

Meanwhile, in order to minimize unintended fluctuations in the difference voltage VDIFF, the driver control circuit 130 may set the driver pull-up path resistance and the driver pull-down path resistance for each driver circuit DRVC with same value based on the various types of control signals CTRL. For example, the driver control circuit 130 may set the first driver pull-up path resistance DPRup_A and the first driver pull-down path resistance DPRdn_A with same value, and may set the second driver pull-up path resistance DPRup_B and the second driver pull-down path resistance DPRdn_B with same value. For a more detailed example, the driver control circuit 130 may set the slice pull-up path resistance SPRup_A and the slice pull-down path resistance SPRdn_A of each slice circuits included in the first driver circuit DRVC_A with same value; and may set the slice pull-up path resistance SPRup_B and the slice pull-down path resistance SPRdn_B of each slice circuits included in the second driver circuit DRVC_B with same value.

Also, in order to make (or facilitate) the receiver driver RXD to generate the reception data D_RX more accurately in the PAM-4 mode, the driver control circuit 130 may determine the first driver pull-up path resistance DPRup_A to be a half of the second driver pull-up path resistance DPRup_B, and may determine the first driver pull-down path resistance DPRdn_A to be a half of the second driver pull-down path resistance DPRdn_B, based on various types of control signals CTRL.

Furthermore, in order to minimize channel reflection of the communication system CMS, the driver control circuit 130 may set the values of the pull-up path resistance (hereinafter referred to as a channel pull-up path resistance CPRup) between the power nodes NVDD and the first channel output pad PAD_P and the pull-down path resistance (hereinafter referred to as a channel pull-down path resistance CPRdn) between the ground nodes NVSS and the first channel output pad PAD_P to predetermined values based on various types of control signals CTRL. For example, in PAM-4 mode, the channel pull-up path resistance CPRup may correspond to a harmonic mean of the first driver pull-up path resistance DPRup_A and the second driver pull-up path resistance DPRup_B; and the channel pull-down path resistance CPRdn may correspond to a harmonic mean of the first driver pull-down path resistance DPRdn_A and the second driver pull-down path resistance DPRdn_B. In this case, the driver control circuit 130 may set the channel pull-up path resistance CPRup and the channel pull-down path resistance CPRdn to predetermined values, by adjusting the first driver pull-up path resistance DPRup_A, the second driver pull-up path resistance DPRup_B, the first driver pull-down path resistance DPRdn_A, and the second driver pull-down path resistance DPRdn_B. On the other hand, in NRZ mode, since the second driver circuit DRVC_B is deactivated, the channel pull-up path resistance CPRup may correspond to the first driver pull-up path resistance DPRup_A, and the channel pull-down path resistance CPRdn may correspond to the first driver pull-down path resistance DPRdn_A. In this case, the driver control circuit 130 may set the channel pull-up path resistance CPRup and the channel pull-down path resistance CPRdn to predetermined values by adjusting the first driver pull-up path resistance DPRup_A and the second driver pull-up path resistance DPRup_B.

Accordingly, the driver control circuit 130 may set each of the first driver pull-up path resistance DPRup_A, the second driver pull-up path resistance DPRup_B, the first driver pull-down path resistance DPRdn_A, and the second driver pull-down path resistance DPRdn_B to a specific value.

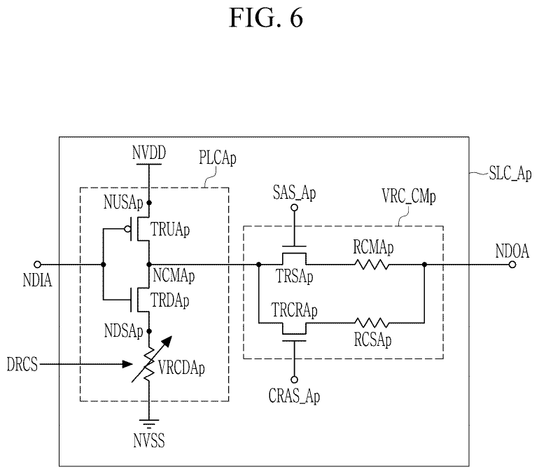

For a more detailed example, in PAM-4 mode, the channel pull-up path resistance CPRup may need to be 50 ohms. That is, the harmonic mean of the first driver pull-up path resistance DPRup_A and the second driver pull-up path resistance DPRup_B may need to be 50 ohms, and the first driver pull-up path resistance DPRup_A may need to be a half of the second driver pull-up path resistance DPRup_B. Accordingly, the driver control circuit 130 may need to set the first driver pull-up path resistance DPRup_A to 75 ohms and the second driver pull-up path resistance DPRup_B to 150 ohms. As another example, in NRZ mode, the channel pull-up path resistance CPRup may need to be 50 ohms. In this case, the driver control circuit 130 may need to set the first driver pull-up path resistance DPRup_A to 50 ohms. However, the scope of the disclosure is not limited to the specific sizes of each of the first driver pull-up path resistance DPRup_A, the second driver pull-up path resistance DPRup_B, the first driver pull-down path resistance DPRdn_A, and the second driver pull-down path resistance DPRdn_B. A specific method in which the driver control circuit 130 sets each of the first driver pull-up path resistance DPRup_A, the second driver pull-up path resistance DPRup_B, the first driver pull-down path resistance DPRdn_A, and the second driver pull-down path resistance DPRdn_B will be described in more detail with reference to FIGS. 6 to 10 below.

In an embodiment, the resistance value of the first driver pull-up path resistance DPRup_A needed for stable operation of the communication system CMS may be referred to as a first driver target pull-up path resistor. Similarly, a resistance value of the first driver pull-down path resistance DPRdn_A needed for stable operation of the communication system CMS may be referred to as a first driver target pull-down path resistor; the resistance value of the second driver pull-up path resistance DPRup_A needed for stable operation of the communication system CMS may be referred to as a second driver target pull-up path resistor; and the resistance value of the second driver pull-down path resistance DPRdn_B needed for stable operation of the communication system CMS may be referred to as a second driver target pull-down path resistor. However, the scope of the disclosure is not limited thereto.

FIG. 6 is a circuit diagram showing the configuration of one slice circuit included in the first driver circuit according to an example embodiment. Hereinafter, with reference to FIGS. 1 to 6, the configuration of a p-th slice circuit SLC_Ap, which is one of the first to n-th slice circuits SLC_A1 to SLC_An (where p is an integer greater than or equal to 1 and less than or equal to n), will be representatively described. However, the scope of the disclosure is not limited thereto, and other slice circuits included in the first driver circuit DRVC_A may also be implemented in a similar manner.

The p-th slice circuit SLC_Ap may include a p-th pulling circuit PLCAp and a p-th variable common resistance circuit VRC_CMp. The p-th pulling circuit PLCAp may be connected between the first driver input node NDIA and a p-th common node NCMAp. The p-th variable common resistance circuit VRC_CMp may be connected between the p-th common node NCMAp and the first driver output node NDOA.

The p-th slice circuit SLC_Ap may receive various types of control signals CTRL from the driver control circuit 130. For example, the p-th slice circuit SLC_Ap may receive a pull-down resistance control signal DRCS, a p-th slice activation signal SAS_Ap, and a p-th common resistance adjustment signal CRAS_Ap from the driver control circuit 130.

The p-th pulling circuit PLCAp may include a p-th pull-up transistor TRUAp, a p-th pull-down transistor TRDAp, and a p-th pull-down variable resistance circuit VRCDAp.

According to an embodiment, a source terminal of the p-th pull-up transistor TRUAp may be connected to a p-th pull-up source node NUSAp. The p-th pull-up source node NUSAp may be connected to the power node NVDD. For example, the p-th pull-up source node NUSAp may be directly connected to the power node NVDD.

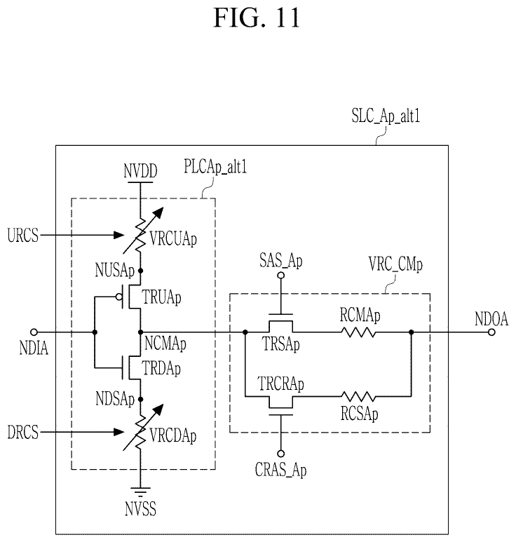

In an embodiment, a pull-up variable resistance circuit may be further connected between the p-th pull-up source node NUSAp and the power node NVDD. An embodiment in which the pull-up variable resistance circuit is connected between the p-th pull-up source node NUSAp and the power node NVDD is described in more detail with reference to FIG. 11 below.

In an example case in which the source terminal of the p-th pull-up transistor TRUAp is directly connected to the power node NVDD, a voltage drop due to a circuit element connected between the power node NVDD and the p-th pull-up source node NUSAp may not occur, so that even in an example case in which the voltage level of the power node NVDD is relatively low (for example, 550 mV or less, or 600 mV or less), a source-gate voltage difference of the p-th pull-up transistor TRUAp may be sufficiently guaranteed. In this case, the first driver circuit DRVC_A may be able to operate normally even in an example case in which the p-th pull-up transistor TRUAp is implemented with smaller size. In other words, in an example case in which the source terminal of the p-th pull-up transistor TRUAp is directly connected to the power node NVDD, the p-th slice circuit SLC_Ap may be implemented based on the p-th pull-up transistor TRUAp with smaller size (e.g., smaller channel width). In this case, sizes of other transistors (e.g., transistors included in the transmission driver TXD and transistors included in a circuit that generates the transmission data D_TX) manufactured with same process as the p-th pull-up transistor TRUAp may also be minimized. Therefore, according to an embodiment of the disclosure, the transmission driver TXD may operate based on the power node NVDD with lower voltage level, and the power consumption of the transmission driver TXD may be minimized. Additionally, according to an embodiment of the disclosure, as the size of the transistors decreases, an equivalent capacitance of the transmission driver TXD side as viewed from the receiver driver RXD may be minimized. In this case, the eye opening area of an eye diagram for the communication system CMS may increase, so the communication stability of the communication system CMS may be improved.

In an example case in which the source terminal of the p-th pull-up transistor TRUAp is directly connected to the power node NVDD, the p-th slice circuit SLC_Ap may be implemented with a smaller number of transistors. For example, according to an embodiment of the disclosure, a pull-up variable resistance circuit may not be included between the p-th pull-up source node NUSAp and the power node NVDD, so that the p-th slice circuit SLC_Ap may be implemented with a smaller number of transistors. In this case, the first drive circuit DRVC_A (and further, the transmission driver TXD) may be implemented with a smaller number of transistors, so that the power consumption and area of the transmission driver TXD may be minimized.

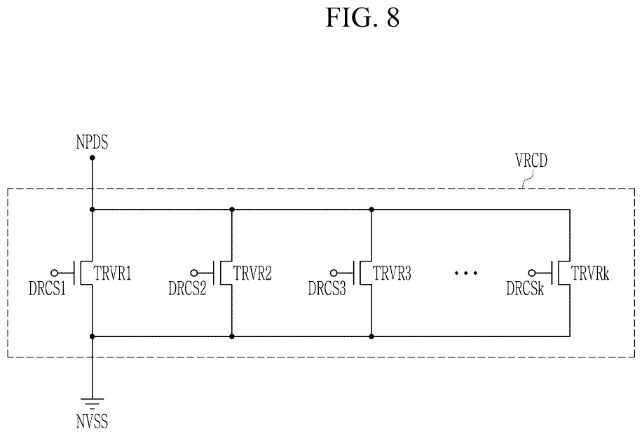

A source terminal of the p-th pull-down transistor TRDAp may be connected to the p-th pull-down source node NDSAp. The p-th pull-down variable resistance circuit VRCDAp may be connected between the p-th pull-down source node NDSAp and the ground node NVSS. A resistance value of the pull-down variable resistance circuit VRCDAp may be adjusted based on a pull-down resistance control signal DRCS. For example, the resistance value of the pull-down variable resistance circuit VRCDAp may be adjusted in response to the pull-down resistance control signal DRCS. An exemplary configuration of a p-th pull-down variable resistance circuit VRCDAp is described in more detail with reference to FIG. 8 below.

In an embodiment, the first to n-th slice circuits SLC_A1 to SLC_An may share the pull-down resistance control signal DRCS. In this case, the pull-down variable resistance circuits VRCDA included in each of the first to n-th slice circuits SLC_A1 to SLC_An may have same resistance value. However, the scope of the disclosure is not limited thereto.

According to an embodiment, drain terminals of each of the p-th pull-up transistor TRUAp and the p-th pull-down transistor TRDAp may be connected to the p-th common node NCMAp.

According to an embodiment, a gate terminal of each of the p-th pull-up transistor TRUAp and the p-th pull-down transistor TRDAp may be connected to the first driver input node NDIA. In this case, one of the p-th pull-up transistor TRUAp and the p-th pull-down transistor TRDAp may be turned on, according to the voltage level of the first driver input node NDIA. For example, based on the value of the upper bit UB of the first channel input data DPin, one of the p-th pull-up transistor TRUAp and the p-th pull-down transistor TRDAp may be turned on. That is, depending on the voltage level of the first driver input node NDIA, a conductive path may be formed between the p-th common node NCMAp and one of the power node NVDD and the ground node NVSS.

The p-th variable common resistance circuit VRC_CMp may include a p-th main common resistor RCMAp, a p-th slice activation transistor TRSAp, a p-th sub common resistor RCSAp, and a p-th common resistance adjustment transistor TRCRAp. The p-th main common resistor RCMAp and the p-th sub common resistor RCSAp may be placed in parallel between the p-th common node NCMAp and the first driver output node NDOA.

The p-th main common resistor RCMAp and the p-th slice activation transistor TRSAp may be connected in series between the p-th common node NCMAp and the first driver output node NDOA. The p-th slice activation transistor TRSAp may operate in response to a p-th slice activation signal SAS_Ap. In an example case in which the p-th slice activation signal SAS_Ap is logic high, a conduction path may be formed between the p-th common node NCMAp and the first driver output node NDOA through the p-th main common resistor RCMAp.

In an example case in which p-th slice activation signal SAS_Ap is logic high, the p-th slice circuit SLC_Ap may be referred to as being in an activated state or in an active state. In an example case in which the p-th slice activation signal SAS_Ap is logic low, the p-th slice circuit SLC_Ap may be referred to as being in a deactivated state.

The p-th sub common resistor RCSAp and the p-th common resistance adjustment transistor TRCRAp may be connected in series between the p-th common node NCMAp and the first driver output node NDOA. The p-th common resistance adjustment transistor TRCRAp may operate in response to a p-th common resistance adjustment signal CRAS_Ap. In an example case in which the p-th common resistance adjustment signal CRAS_Ap is logic high, a conductive path may be formed between the p-th common node NCMAp and the first driver output node NDOA through the p-th sub common resistor RCSAp.

For a more concise explanation, FIG. 6 illustrates an embodiment in which a p-th slice activation transistor TRSAp is connected between the p-th common node NCMAp and the p-th main common resistor RCMAp, and the p-th common resistance adjustment transistor TRCRAp is connected between the p-th common node NCMAp and the p-th sub common resistor RCSAp, but the scope of the disclosure is not limited thereto. For example, the p-th slice activation transistor TRSAp may be connected between the first driver output node NDOA and the p-th main common resistor RCMAp, and the p-th common resistance adjustment transistor TRCRAp may be connected between the first driver output node NDOA and the p-th sub common resistor RCSAp. That is, the scope of the disclosure is not limited to a specific implementation scheme of the p-th variable common resistance circuit VRC_CMp.

According to an embodiment, the driver control circuit 130 may always set the p-th common resistance adjustment signal CRAS_Ap to logic low in an example case in which the p-th slice activation signal SAS_Ap being set to logic low. That is, when the p-th slice activation signal SAS_Ap is logic low, the configuration and operation of the p-th slice circuit SLC_Ap may not affect the first driver output node NDOA. In other words, in an example case in which the p-th slice circuit SLC_Ap is in the deactivated state, the first driver pull-up path resistance DPRup_A and the second driver pull-up path resistance DPRup_B may be determined independently of the components included in the p-th slice circuit SLC_Ap.

In an example case in which the driver control circuit 130 sets the p-th slice activation signal SAS_Ap to logic high, the logic level of the p-th common resistance adjustment signal CRAS_Ap may be set to logic high or logic low depending on the operation mode of the transmission driver TXD. For example, when the transmission driver TXD operates in PAM-4 mode, the driver control circuit 130 may set the p-th common resistance adjustment signal CRAS_Ap to logic low; and when the transmission driver TXD operates in NRZ mode, the driver control circuit 130 may set the p-th common resistance adjustment signal CRAS_Ap to either of logic high or logic low (e.g., when the p-th slice circuit SLC_Ap being in deactivated state).

Therefore, the resistance value of the p-th variable common resistance circuit VRC_CMp may vary depending on the p-th common resistance adjustment signal CRAS_Ap. For example, while the p-th slice circuit SLC_Ap is activated, a resistance value of the variable common resistance circuit VRC_CMp may be determined as the resistance value of the p-th main common resistor RCMAp (for example, when the transmission driver TXD operates in PAM-4 mode), or may be determined as a harmonic mean of the resistance value of the p-th main common resistor RCMAp and the resistance value of the p-th sub common resistor RCSAp (for example, when the transmission driver TXD operates in NRZ mode). For example, the resistance value of the p-th variable common resistance circuit VRC_CMp may also vary depending on the turn-on resistance of the p-th slice activation transistor TRSAp and the p-th common resistance adjustment transistor TRCRAp, but for a more concise explanation, in the following, the turn-on resistance of the p-th slice activation transistor TRSAp and the p-th common resistance adjustment transistor TRCRAp is assumed to be so small enough to be ignored.

From this perspective, in an example case in which the transmission driver TXD operates in PAM-4 mode, the first driver circuit DRVC_A may also be referred to as operating in PAM-4 mode, and in an example case in which the transmission driver TXD operates in NRZ mode, the first driver circuit DRVC_A may also be referred to as operating in NRZ mode. That is, when at least one common resistance adjustment transistor TRCRA of the first to n-th slice circuits SLC_A1 to SLC_An is turned on, the first driver circuit DRVC_A may be referred to as operating in the NRZ mode, and when all common resistance adjustment transistors TRCRA of the first to n-th slice circuits SLC_A1 to SLC_An are turned off, the first driver circuit DRVC_A may be referred to as operating in the PAM-4 mode.

According to an embodiment, a sum of the turn-on resistance value of the p-th pull-up transistor TRUAp and the resistance value of the p-th variable common resistance circuit VRC_CMp may be equivalently expressed as the slice pull-up path resistance SPRup_A for the p-th slice circuit SLC_Ap.

According to an embodiment, a sum of the resistance value of the p-th pull-down variable resistance circuit VRCDAp, the turn-on resistance value of the p-th pull-down transistor TRDAp, and the resistance value of the p-th variable common resistance circuit VRC_CMp may be equivalently expressed as the slice pull-down path resistance SPRdn_A for the p-th slice circuit SLC_Ap.

That is, the driver control circuit 130 may adjust the slice pull-up path resistance SPRup_A and the slice pull-down path resistance SPRdn_A of the p-th slice circuit SLC_Ap. Similarly, the driver control circuit 130 may adjust the slice pull-up path resistance SPRup_A and the slice pull-down path resistance SPRdn_A of each of the first to n-th slice circuits SLC_A1 to SLC_An. Therefore, according to an embodiment of the disclosure, the driver control circuit 130 may control the first driver pull-up path resistance DPRup_A and the first driver pull-down path resistance DPRdn_A based on the various types of control signals CTRL.

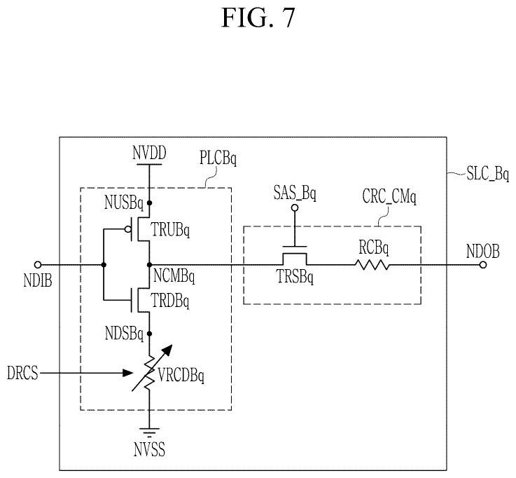

FIG. 7 is a circuit diagram showing the configuration of one slice circuit included in the second driver circuit according to an embodiment. Hereinafter, with reference to FIGS. 1 to 7, the configuration of a q-th slice circuit SLC_Bq, which is one of the first to m-th slice circuits SLC_B1 to SLC_Bm (where q is an integer greater than or equal to 1 and less than or equal to m), will be representatively described. However, the scope of the disclosure is not limited thereto, and other slice circuits included in the second driver circuit DRVC_B may also be implemented in a similar manner.

The q-th slice circuit SLC_Bq may include a q-th pulling circuit PLCBq and a q-th constant common resistance circuit CRC_CMq. The q-th pulling circuit PLCBq may be connected between the second driver input node NDIB and the q-th common node NCMBq. The q-th constant common resistance circuit CRC_CMq may be connected between the q-th common node NCMBq and the second driver output node NDOB.

The q-th slice circuit SLC_Bq may receive various types of control signals CTRL from the driver control circuit 130. For example, the q-th slice circuit SLC_Bq may receive a pull-down resistance control signal DRCS and a q-th slice activation signal SAS_Bq from the driver control circuit 130.

In an embodiment, the first to m-th slice circuits SLC_B1 to SLC_Bm may share the pull-down resistance control signal DRCS. In this case, the pull-down variable resistance circuits VRCDB included in each of the first to m-th slice circuits SLC_B1 to SLC_Bm may have same resistance value. However, the scope of the disclosure is not limited thereto. For example, the driver control circuit 130 may provide different pull-down resistance control signals DRCS to each of the first to m-th slice circuits SLC_B1 to SLC_Bm.

In an embodiment, the first to n-th slice circuits SLC_A1 to SLC_An and the first to m-th slice circuits SLC_B1 to SLC_Bm may share the pull-down resistance control signal DRCS. However, the scope of the disclosure is not limited thereto. For example, the driver control circuit 130 may provide different pull-down resistance control signals DRCS to each driver circuit DRVC.

The q-th pull-up circuit PLCBq may include a q-th pull-up transistor TRUBq, a q-th pull-down transistor TRDBq, and a q-th pull-down variable resistance circuit VRCDBq. A gate terminal of each of the q-th pull-up transistor TRUBq and the q-th pull-down transistor TRDBq may be connected to the second driver input node NDIB. The configuration of the q-th pulling circuit PLCBq is similar to the configuration of the p-th pulling circuit PLCAp described above with reference to FIG. 6, so a detailed description thereof is omitted.

The q-th constant common resistance circuit CRC_CMq may include a q-th common resistor RCBq and a q-th slice activation transistor TRSBq. The q-th common resistor RCBq and the q-th slice activation transistor TRSBq may be connected in series between the q-th common node NCMBq and the second driver output node NDOB. Accordingly, the resistance value of the q-th constant common resistance circuit CRC_CMq may be determined based on the q-th common resistor RCBq. For example, the resistance value of the q-th constant common resistance circuit CRC_CMq may also vary depending on a turn-on resistance of the q-th slice activation transistor TRSBq, but for the sake of a more concise explanation, the turn-on resistance of the q-th slice activation transistor TRSBq is assumed to be small enough to be ignored.

In an embodiment, the resistance value of the q-th common resistor RCBq may be determined to be equal to the resistance value of the p-th main common resistor RCMAp.

The q-th slice activation transistor TRSBq may operate based on a q-th slice activation signal SAS_Bq. For example, the q-th slice activation transistor TRSBq may operate in response to a q-th slice activation signal SAS_Bq. In an example case in which the q-th slice activation signal SAS_Bq is logic high, a conductive path may be formed between the q-th common node NCMBq and the second driver output node NDOB through the q-th common resistor RCBq.

In an example case in which the q-th slice activation signal SAS_Bq is logic high, the q-th slice circuit SLC_Bq may be referred to as being in an activated state or an active state. In an example case in which the q-th slice activation signal SAS_Bq is logic low, the q-th slice circuit SLC_Bq may be referred to as being in a deactivated state or an inactive state.

The driver control circuit 130 may determine the logic level of the q-th slice activation signal SAS_Bq according to an operation mode of the transmission driver TXD. In an example case in which the transmission driver TXD operates in NRZ mode, the driver control circuit 130 may set the q-th slice activation signal SAS_Bq with logic low. On the other hand, in an example case in which the transmission driver TXD operates in PAM-4 mode, the driver control circuit 130 may set the q-th slice activation signal SAS_Bq with either of logic high or logic low.

The sum of the turn-on resistance value of the q-th pull-up transistor TRUBq and the resistance value of the q-th constant common resistance circuit CRC_CMq may be equivalently expressed as the slice pull-up path resistance SRPup_B for the q-th slice circuit SLC_Bq.

The sum of the resistance value of the q-th pull-down variable resistance circuit VRCDBq, a turn-on resistance value of the q-th pull-down transistor TRDBq, and the resistance value of the q-th constant common resistance circuit CRC_CMq may be equivalently expressed as the slice pull-down path resistance SPRdn_B for the q-th slice circuit SLC_Bq.

In an example case in which the transmission driver TXD operates in PAM-4 mode, the driver control circuit 130 may activate some of the first to m-th slice circuits SLC_B1 to SLC_Bm. In this case, the second driver pull-up path resistance DPRup_B may be adjusted according to a number of activated slice circuits, and the second driver pull-down path resistance DPRdn_B may be adjusted according to a number of activated slice circuits and the resistance value of the pull-down variable resistance circuit VRCDB included in each of the activated slice circuits.

In an example case in which the transmission driver TXD operates in NRZ mode, the transmission driver TXD may deactivate all of the first to m-th slice circuits SLC_B1 to SLC_Bm. In this case, the second driver output node NDOB may be electrically floated. In other words, components included in the first to m-th slice circuits SLC_B1 to SLC_Bm may not affect to a voltage level of the second driver output node NDOB. According to an embodiment, the components included in the first to m-th slice circuits SLC_B1 to SLC_Bm further may not affect to a voltage level of the first channel output pad PAD_P.

From this perspective, in an example case in which the transmission driver TXD operates in PAM-4 mode, the second driver circuit DRVC_B may also be referred to as operating in PAM-4 mode, and in an example case in which the transmission driver TXD operates in NRZ mode, the second driver circuit DRVC_B may also be referred to as operating in NRZ mode. That is, in an example case in which at least one of the first to m-th slice circuits SLC_B1 to SLC_Bm is activated, the second driver circuit DRVC_B may be referred to as operating in PAM-4 mode, and in an example case in which all of the first to m-th slice circuits SLC_B1 to SLC_Bm are deactivated, the second driver circuit DRVC_B may be referred to as operating in NRZ mode.

In an in an example case in which the second driver circuit DRVC_B is deactivated while the transmission driver TXD operates in NRZ mode, the power consumption of the transmission driver TXD may be minimized. For example, in a case in which only the first driver circuit DRVC_A operates while the transmission driver TXD operates in NRZ mode, the power consumption may become approximately half in comparison with a case where both the first driver circuit DRVC_A and the second driver circuit DRVC_B operate while the transmission driver TXD operates in NRZ mode. That is, according to the embodiment of the disclosure, the operating efficiency of the transmission driver TXD in NRZ mode may be maximized.

FIG. 8 is a circuit diagram showing the configuration of the pull-down variable resistance circuit of FIGS. 6 and 7 according to an embodiment. Referring to FIGS. 1 to 8, a pull-down variable resistance circuit VRCD may be connected between a pull-down source node NPDS and a ground node NVSS. In an example case in which the pull-down variable resistance circuit VRCD is the p-th pull-down variable resistance circuit VRCDAp described above with reference to FIG. 6, the pull-down source node NPDS may correspond to the p-th pull-down source node NPDSAp. In an example case in which the pull-down variable resistance circuit VRCD is the q-th pull-down variable resistance circuit VRCDBq described above with reference to FIG. 7, the pull-down source node NPDS may correspond to the q-th pull-down source node NPDSBq.

The pull-down variable resistance circuit VRCD may include first to k-th variable resistance transistors TRVR1 to TRVRk. The pull-down variable resistance circuit VRCD may receive the pull-down resistance control signal DRCS. The pull-down resistance control signal DRCS may include first to k-th pull-down resistance control signals DRCS1 to DRCSk. The first to k-th variable resistance transistors TRVR1 to TRVRk may operate based on the logic levels of the first to k-th pull-down resistance control signals DRCS1 to DRCSk, respectively. In this case, a resistance value of the pull-down variable resistance circuit VRCD may be determined based on turn-on resistance values of the first to k-th variable resistance transistors TRVR1 to TRVRk.

That is, according to an embodiment of the disclosure, even in an example case in which the characteristics (e.g., resistance value) of each circuit element included in the communication system CMS vary depending on various factors such as temperature, humidity, communication speed, etc., the driver control circuit 130 may set the slice pull-up path resistance and the slice pull-down path resistance for each slice circuit with same value, by adjusting the pull-down variable resistance circuit VRCD.

In an embodiment, the turn-on resistance values of each of the first to k-th variable resistance transistors TRVR1 to TRVRk may be the same or different.

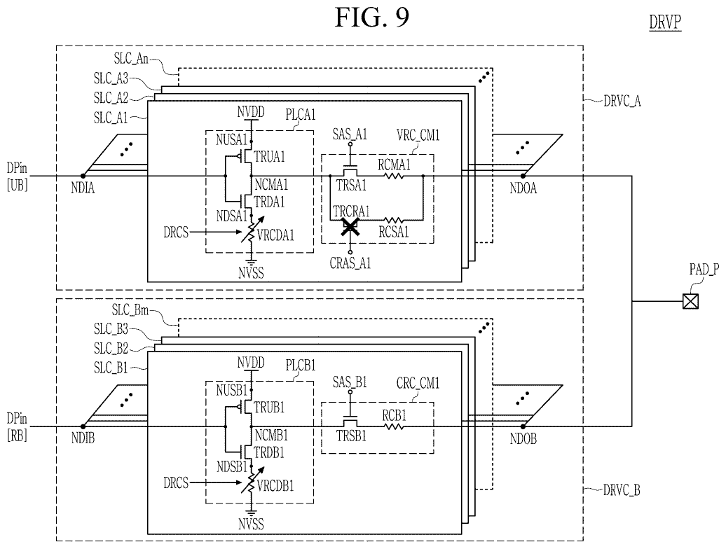

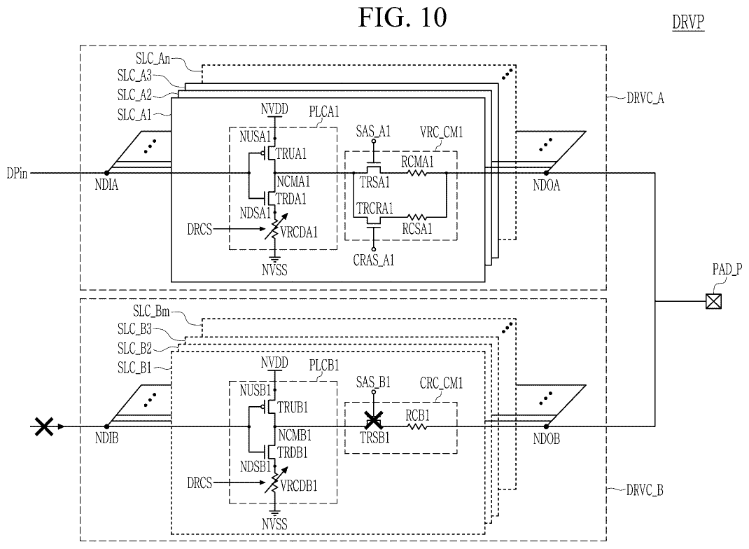

FIGS. 9 and 10 are drawings showing the specific operation method of the first channel driver according to an embodiment. Hereinafter, an embodiment in which the first channel driver DRVP operates in PAM-4 mode is described with reference to FIG. 9, and an embodiment in which the first channel driver DRVP operates in NRZ mode is described with reference to FIG. 10.

Referring to FIGS. 1 to 9, the first channel driver DRVP may include the first driver circuit DRVC_A and the second driver circuit DRVC_B. The first driver circuit DRVC_A may include the first driver input node NDIA, the first driver output node NDOA, and the first to n-th slice circuits SLC_A1 to SLC_An. The second driver circuit DRVC_B may include the second driver input node NDIB, the second driver output node NDOB, and the first to m-th slice circuits SLC_B1 to SLC_Bm.

The driver control circuit 130 may activate at least one of the first to n-th slice circuits SLC_A1 to SLC_An. The driver control circuit 130 may turn off the common resistance adjustment transistor TRCRA of each of the first to n-th slice circuits SLC_A1 to SLC_An. In this case, a size of the slice pull-up path resistance SPRup_A of each of activated slice circuits among the first to n-th slice circuits SLC_A1 to SLC_An may be determined by a sum of the turn-on resistance value of the pull-up transistor TRUA and the main common resistor RCMA, and a size of the slice pull-down path resistance SPRdn_A of each of activated slice circuits among the first to n-th slice circuits SLC_A1 to SLC_An may be determined by a sum of the resistance value of the pull-down variable resistance circuit VRCDA, the turn-on resistance value of the pull-down transistor TRDA, and the resistance value of the main common resistor RCMA.

Therefore, the size of the first driver pull-up path resistance DPRup_A may be a value obtained by dividing the slice pull-up path resistance SPRup_A by a number of activated slice circuits among the first to n-th slice circuits SLC_A1 to SLC_An. The size of the second driver pull-up path resistance DPRup_B may be a value obtained by dividing the slice pull-down path resistance SPRdn_A by a number of activated slice circuits among the first to n-th slice circuits SLC_A1 to SLC_An.

In other words, the driver control circuit 130 may set the first driver pull-up path resistance DPRup_A based on a number of activated slice circuits among the first to n-th slice circuits SLC_A1 to SLC_An, and may set the first driver pull-down path resistance DPRdn_A based on a number of activated slice circuits among the first to n-th slice circuits SLC_A1 to SLC_An, and the resistance value of the pull-down variable resistance circuit VRCDA.

The driver control circuit 130 may activate at least one of the first to m-th slice circuits SLC_B1 to SLC_Bm.

A size of the slice pull-up path resistance SPRup_B of each of activated slice circuits among the first to m-th slice circuits SLC_B1 to SLC_Bm may be determined by a sum of the turn-on resistance value of the pull-up transistor TRUB and the common resistor RCB; and a size of the slice pull-down path resistance SPRdn_B of each of the activated slice circuits among the first to m-th slice circuits SLC_B1 to SLC_Bm may be determined by a sum of the resistance value of the pull-down variable resistance circuit VRCDB, the turn-on resistance of the pull-down transistor TRDB, and the resistance value of the common resistor RCB.

Therefore, the size of the second driver pull-up path resistance DPRup_B may be a value obtained by dividing the slice pull-up path resistance SPRup_B by a number of activated slice circuits among the activated first to m-th slice circuits SLC_B1 to SLC_Bm. The size of the second driver pull-down path resistance DPRdn_B may be a value obtained by dividing the slice pull-down path resistance SPRdn_B by a number of activated slice circuits among the first to m-th slice circuits SLC_B1 to SLC_Bm.

In other words, the driver control circuit 130 may set the second driver pull-up path resistance DPRup_B based on the number of activated slice circuits among the first to m-th slice circuits SLC_B1 to SLC_Bm, and may set the second driver pull-down path resistance DPRdn_B based on the number of activated slice circuits among the first to m-th slice circuits SLC_B1 to SLC_Bm, and the resistance value of the pull-down variable resistance circuit VRCDB.

According to an embodiment, based on various types of control signals CTRL, the driver control circuit 130 may determine the first driver pull-up path resistance DPRup_A to be half of the second driver pull-up path resistance DPRup_B and may determine the first driver pull-down path resistance DPRdn_A to be half of the second driver pull-down path resistance DPRdn_B.

In an embodiment, the pulling circuits PLCA and the pulling circuits PLCB included in the first channel driver DRVP may be implemented identically to each other. Resistance values of the main common resistors RCMA and the common resistor RCB included in the first channel driver DRVP may be implemented to be identical to each other. In this case, the slice pull-up path resistance SPRup_A and the slice pull-up path resistance SPRup_B may be equal to each other, and the slice pull-down path resistance SPRdn_A and the slice pull-down path resistance SPRdn_B may be equal to each other. Accordingly, the driver control circuit 130 may control a number of activated slice circuits among the first to n-th slice circuits SLC_A1 to SLC_An to be twice a number of activated slice circuits among the first to m-th slice circuits SLC_B1 to SLC_Bm. For example, the driver control circuit 130 may set ‘2N’ of the first to n-th slice activation signals SAS_A1 to SAS_An to logic high, and may set ‘N’ of the first to m-th slice activation signals SAS_B1 to SAS_Bm to logic high.

In an embodiment, the driver control circuit 130 may activate two of the first to n-th slice activation signals SAS_A1 to SAS_An for each activating one of the first to m-th slice activation signals SAS_B1 to SAS_Bm. For example, one of the first to m-th slice activation signals SAS_B1 to SAS_Bm and two of the first to n-th slice activation signals SAS_A1 to SAS_An may be implemented to share the same logic level. However, the scope of the disclosure is not limited to a specific manner how the driver control circuit 130 controls the first to n-th slice activation signals SAS_A1 to SAS_An and the first to m-th slice activation signals SAS_B1 to SAS_Bm.

In an embodiment, ‘n’ may be double of ‘m’, where m and n are integers. However, the scope of the disclosure is not limited thereto.

In an embodiment, characteristics (e.g., resistance value) of each circuit element included in the communication system CMS may vary depending on various factors such as temperature, humidity, communication speed, etc. However, according to an embodiment of the disclosure, the driver control circuit 130 may adjust each of the first driver pull-up path resistance DPRup_A, the first driver pull-down path resistance DPRdn_A, the second driver pull-up path resistance DPRup_B, and the second driver pull-down path resistance DPRdn_B based on various types of control signals CTRL, so that the operation stability of the communication system CMS may be guaranteed even in various communication environments.

In FIG. 10, the driver control circuit 130 may activate at least one of the first to n-th slice circuits SLC_A1 to SLC_An. The driver control circuit 130 may turn on the common resistance adjustment transistor TRCRA of each of the activated slice circuits among the first to n-th slice circuits SLC_A1 to SLC_An. In this case, the size of the slice pull-up path resistance SPRup_A of each of activated slice circuits among the first to n-th slice circuits SLC_A1 to SLC_An may be determined as a value obtained by adding the turn-on resistance of the pull-up transistor TRUA to a harmonic mean of the main common resistor RCMA and the sub common resistor RCSA; and the size of the slice pull-down path resistance SPRdn_A of each of activated slice circuits among the first to n-th slice circuits SLC_A1 to SLC_An may be determined as a value obtained by summing the turn-on resistance of the pull-down transistor TRDA, the resistance value of the pull-down variable resistance circuit VRCDA and a harmonic mean of the main common resistor RCMA and the sub common resistor RCSA.

The differential driving circuit 110 may not provide data to the first to m-th slice circuits SLC_B1 to SLC_Bm. Accordingly, the driver control circuit 130 may deactivate each of the first to m-th slice circuits SLC_B1 to SLC_Bm. That is, the driver control circuit 130 may electrically float the second driver output node NDOB. In this case, the channel pull-up path resistance CPRup and the channel pull-down path resistance CPRdn may be determined only based on the first driver circuit DRVC_A.

FIG. 11 is a circuit diagram showing the configuration of one slice circuit included in the first driver circuit according to another embodiment. Referring to FIGS. 1 to 11, the p-th slice circuit SLC_Ap may also be implemented with the following p-th slice circuit SLC_Ap_alt1. Hereinafter, differences between the p-th slice circuit SLC_Ap and the p-th slice circuit SLC_Ap_alt1 will be mainly explained.

The p-th slice circuit SLC_Ap_alt1 may include a p-th pulling circuit PLCAp_alt1 and a p-th variable common resistance circuit VRC_CMp. The p-th pulling circuit PLCAp_alt1 may be connected between the first driver input node NDIA and a p-th common node NCMAp. The p-th variable common resistance circuit VRC_CMp may be connected between the p-th common node NCMAp and the first driver output node NDOA.

The p-th pulling circuit PLCAp_alt1 may include a p-th pull-up transistor TRUAp, a p-th pull-down transistor TRDAp, a p-th pull-up variable resistance circuit VRCUAp, and a p-th pull-down variable resistance circuit VRCDAp. The p-th pull-up variable resistance circuit VRCUAp may be connected between the power node NVDD and the p-th pull-up source node NUSAp. The resistance value of the pull-up variable resistance circuit VRCUAp may be adjusted in response to a pull-up resistance control signal URCS.

The slice pull-up path resistance SPRup_A for the p-th slice circuit SLC_Ap_alt1 may be determined by a sum of a resistance value of the p-th pull-up variable resistance circuit VRCUAp, a turn-on resistance value of the p-th pull-up transistor TRUAp, and a resistance value of the p-th variable common resistance circuit VRC_CMp. In this case, unlike what was described above with reference to FIGS. 1 to 10, the driver control circuit 130 will be able to more precisely adjust the slice pull-up path resistance SPRup_A and the first driver pull-up path resistance DPRup_A.

In an embodiment, the p-th pull-up variable resistance circuit VRCUAp may be implemented with a plurality of PMOS transistors connected between the power node NVDD and the p-th pull-up source node NUSAp, similar to that described above with reference to FIG. 8. However, the scope of the disclosure is not limited thereto.

In an embodiment, the implementation of the p-th pulling circuit PLCAp_alt1 may also be applied to the q-th pulling circuit PLCBq included in the q-th slice circuit SLC_Bq. However, the scope of the disclosure is not limited thereto.

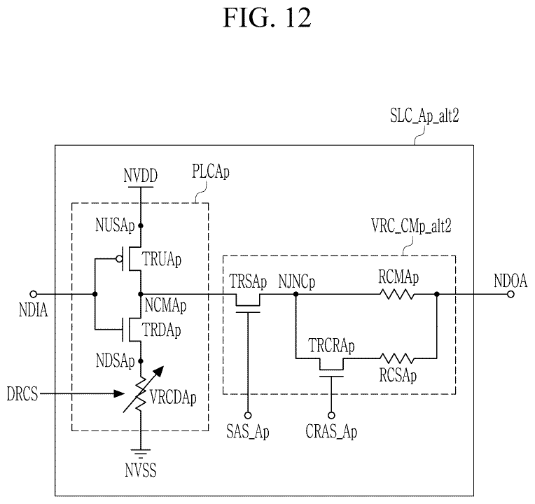

FIG. 12 is a circuit diagram showing the configuration of one slice circuit included in the first driver circuit according to an embodiment. Referring to FIGS. 1 to 10 and 12, the p-th slice circuit SLC_Ap may be implemented with the following p-th slice circuit SLC_Ap_alt2. Below, differences between the p-th slice circuit SLC_Ap and the p-th slice circuit SLC_Ap_alt2 will be mainly explained.

The p-th slice circuit SLC_Ap_alt2 may include a p-th pulling circuit PLCAp and a p-th variable common resistance circuit VRC_CMp_alt2. The p-th pulling circuit PLCAp may be connected between the first driver input node NDIA and a p-th common node NCMAp. The p-th variable common resistance circuit VRC_CMp_alt2 may be connected between the p-th common node NCMAp and the first driver output node NDOA.

The p-th variable common resistance circuit VRC_CMp may include a p-th main common resistor RCMAp, a p-th slice activation transistor TRSAp, a p-th sub common resistor RCSAp, and a p-th common resistance adjustment transistor TRCRAp.

The p-th slice activation transistor TRSAp may be connected between the p-th common node NCMAp and the p-th junction node NJNCp. The p-th slice activation transistor TRSAp may operate in response to a p-th slice activation signal SAS_Ap.

The p-th main common resistor RCMAp and the p-th sub common resistor RCSAp may be located in parallel between the p-th common node NCMAp and the first driver output node NDOA. For example, the p-th main common resistor RCMAp and the p-th sub common resistor RCSAp may be connected in parallel between the p-th junction node NJNCp and the first driver output node NDOA. For example, the p-th sub common resistor RCSAp and the p-th common resistance adjustment transistor TRCRAp may be connected in series between the p-th junction node NJNCp and the first driver output node NDOA. The p-th main common resistor RCMAp may be connected in parallel with the p-th sub common resistor RCSAp and the p-th common resistance adjustment transistor TRCRAp, between the p-th junction node NJNCp and the first driver output node NDOA.

The p-th common resistance adjustment transistor TRCRAp may operate in response to the p-th common resistance adjustment signal CRAS_Ap. In an example case in which the p-th common resistance adjustment signal CRAS_Ap is logic high, a conduction path through the p-th sub common resistor RCSAp may be formed between the p-th junction node NJNCp and the first driver output node NDOA. In this case, the resistance value of the p-th variable common resistance circuit VRC_CMp_alt2 may decrease.

Meanwhile, the driver control circuit 130 may eliminate an influence of components of the p-th slice circuit SLC_Ap_alt2 on the first driver output node NDOA by setting the p-th slice activation signal SAS_Ap to logic low. In other words, the driver control circuit 130 may prevent that a conductive path being formed between the p-th common node NCMAp and the first driver output node NDOA simply by setting the p-th slice activation signal SAS_Ap to logic low regardless of the logic level of the p-th common resistance adjustment signal CRAS_Ap. In this case, the driver control circuit 130 may freely determine the logic level of the p-th common resistance adjustment signal CRAS_Ap even in an example case in which the p-th slice activation signal SAS_Ap is set to logic low. However, the scope of the disclosure is not limited thereto.

For a more concise explanation, FIG. 12 is representatively described as an embodiment in which a p-th slice activation transistor TRSAp is connected between a p-th common node NCMAp and a p-th junction node NJNCp, but the scope of the disclosure is not limited thereto. For example, the p-th slice activation transistor TRSAp may be connected between the p-th variable common resistance circuit VRC_CMp_alt2 and the first driver output node NDOA.

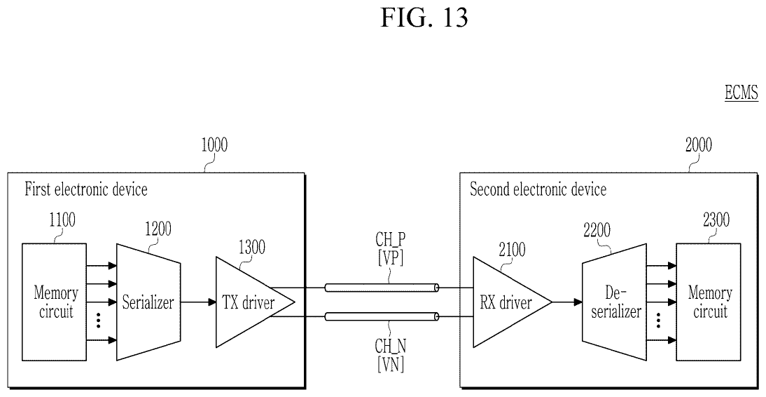

FIG. 13 is a block diagram showing an electronic communication system according to an embodiment. Referring to FIGS. 1 to 13, an electronic communication system ECMS may include a first electronic device 1000 and a second electronic device 2000.

In an embodiment, each of the first electronic device 1000 and the second electronic device 2000 may be one of various types of electronic devices, such as an application processor (AP), a modem device, an image sensor device, a display device, a storage device, a memory device, and the like. However, the disclosure is not limited thereto, and as, the first electronic device 1000 and the second electronic device 2000 may include another type of electronic device.

The first electronic device 1000 may include a memory circuit 1100, a serializer 1200, and a transmission driver 1300. The second electronic device 2000 may include a receiver driver 2100, a de-serializer 2200, and a memory circuit 2300. However, the disclosure is not limited thereto, and as such, the first electronic device 1000 and the second electronic device 2000 may include one or more other components. For example, the first electronic device 1000 may include a receiver driver and a de-serializer, and the second electronic device 2000 may include a transmission driver and a serializer.

The memory circuit 1100 may store data to be provided to the second electronic device 2000. For example, the memory circuit 1100 may be a volatile memory such as a static random access memory (SRAM), a dynamic random access memory (DRAM), or a nonvolatile memory such as a flash memory. However, the scope of the disclosure is not limited to a specific type of memory circuit 1100. For example, the memory circuit 1100 may be implemented as any type of data storage circuit, such as a flip-flop, a latch, etc.

The serializer 1200 may receive data stored in the memory circuit 1100 in unit of a plurality of bits. For example, data stored in the memory circuit 1100 may be received in 16-bit unit. The serializer 1200 may serialize the received data. For example, 16-bit data received in parallel may be sequentially provided to the transmission driver 1300 in units of 1-bit or 2-bits.

The transmission driver 1300 may receive the data from the serializer 1200. The transmission driver 1300 may correspond to the transmission driver TXD described above with reference to FIGS. 1 to 12. In this case, the data provided to the transmission driver 1300 may correspond to transmission data D_TX.

In an embodiment, the transmission driver 1300 and the serializer 1200 may be generated based on the same process. In this case, the transmission driver 1300 and the serializer 1200 may be implemented with transistors of the same size. However, the disclosure is not limited thereto, and as such, according to an embodiment of the disclosure, a pull-up transistor included in the transmission driver 1300 may be implemented with a smaller size. In this case, since both the transistors included in the transmission driver 1300 and the serializer 1200 may be implemented with smaller size, the power consumption of the first electronic device 1000 may be minimized.

The transmission driver 1300 may be connected to the first channel CHP and the second channel CHN. The transmission driver 1300 may control the first channel voltage VP and the second channel voltage VN based on the received data.

The receiver driver 2100 may decode data provided from the first electronic device 1000 based on the difference between the first channel voltage VP and the second channel voltage VN. The receiver driver 2100 may correspond to the receiver driver RXD described above with reference to FIG. 1. In this case, the data decoded by the receiver driver 2100 may correspond to the reception data D_RX. For example, the receiver driver 2100 may generate 1-bit or 2-bit data per unit interval UI.

In an embodiment, the receiver driver 2100 may include a resistor connected between the first channel CHP and the second channel CHN. The channel pull-up path resistance and the channel pull-down path resistance described with reference to FIGS. 1 to 12 above may be determined based on the size of the resistance connected between the first channel CHP and the second channel CHN. However, the scope of the disclosure is not limited thereto.

The de-serializer 2200 may receive data from the receiver driver 2100. The de-serializer 2200 may accumulate data provided from the receiver driver 2100 and store the accumulated data in the memory circuit 2300. The memory circuit 2300 may be implemented as any type of data storage circuit, similar to the memory circuit 1100. In this case, data stored in the memory circuit 2300 may be used for the operation of the second electronic device 2000.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A channel driver comprising:
a first driver input node configured to receive a first channel input data;
a first driver output node connected to a channel output pad; and
a first plurality of slice circuits connected in parallel between the first driver input node and the first driver output node,
wherein a first slice circuit, among the first plurality of slice circuits, comprises:
a first pulling circuit connected between the first driver input node and a first common node; and
a first variable common resistance circuit connected between the first common node and the first driver output node, the first variable common resistance circuit configured to operate based on a first common resistance adjustment signal.

2. The channel driver of claim 1, wherein the first pulling circuit comprises:
a first pull-up transistor configured to operate based on a voltage level of the first driver input node;
a first pull-down transistor connected to the first pull-up transistor through the first common node, the first pull-down transistor configured to operate based on the voltage level of the first driver input node; and
a pull-down variable resistance circuit connected between a source terminal of the first pull-down transistor and a ground node.

3. The channel driver of claim 2, wherein a source terminal of the first pull-up transistor is connected to a power node.

4. The channel driver of claim 1, wherein the first variable common resistance circuit comprises:
a first common resistor and a second common resistor, which are provided in parallel between the first common node and the first driver output node; and
a common resistance adjustment transistor connected between the second common resistor and one of the first common node and the first driver output node, the common resistance adjustment transistor configured to operate based on the first common resistance adjustment signal.

5. The channel driver of claim 4, wherein the first variable common resistance circuit further comprises:
a first slice activation transistor, which is connected between the first common resistor and one of the first common node and the first driver output node, the first slice activation transistor being configured to operate based on a first slice activation signal.

6. The channel driver of claim 4, wherein the first common resistance adjustment signal is configured to:
have a first logic level while the channel driver operates in a non-return to zero (NRZ) mode; and
have a second logic level while the channel driver operates in a pulse amplitude modulation with 4-level (PAM-4) mode.

7. The channel driver of claim 6, further comprising:
a second driver input node configured to receive a second channel input data;
a second driver output node connected to the channel output pad; and
a second plurality of slice circuits connected in parallel between the second driver input node and the second driver output node,
wherein a second slice circuit, among the second plurality of slice circuits, comprises:
a second pulling circuit connected between the second driver input node and a second common node; and
a constant common resistance circuit connected between the second common node and the second driver output node.

8. The channel driver of claim 7, wherein the constant common resistance circuit comprises:
a second common resistor provided between the second common node and the second driver output node, the second common resistor having a resistance value same as the first common resistor.

9. The channel driver of claim 7, wherein:
while the channel driver operates in the NRZ mode, the second plurality of slice circuits are deactivated, and
while the channel driver operates in the PAM-4 mode, at least one of the second plurality of slice circuits are activated.

10. The channel driver of claim 9, wherein:
while the channel driver operates in the PAM-4 mode, a first number of activated slice circuits among the first plurality of slice circuits is twice a second number of activated slice circuits among the second plurality of slice circuits.

11. The channel driver of claim 1, wherein:
the first plurality of slice circuits are included in a first driver circuit,
the first plurality of slice circuits are configured to be controlled based on a plurality of slice activation signals, respectively,
a driver pull-up path resistance for the first driver circuit is determined based on a number of activated slice circuits among the first plurality of slice circuits and a resistance value of the first variable common resistance circuit.

12. The channel driver of claim 1, wherein:
the first plurality of slice circuits comprises a third slice circuit, and
wherein the third slice circuit comprises:
a third pulling circuit connected between the first driver input node and a third common node; and
a second variable common resistance circuit, which is connected between the third common node and the first driver output node and configured to operate based on a second common resistance adjustment.

13. A transmission driver comprising:
a first driver circuit comprising a first driver output node connected to a first channel output pad;
a second driver circuit comprising a second driver output node connected to the first channel output pad; and
a driver control circuit configured to:
activate the first driver circuit during a first time period in a case in which the first driver circuit and the second driver circuit operate in a non-return to zero (NRZ) mode, and
activate the first driver circuit and the second driver circuit during a second time period in a case in which the first driver circuit and second driver circuit operate in a pulse amplitude modulation with 4-level (PAM-4) mode, wherein the second driver output node is configured to be electrically floated during the first time period.

14. The transmission driver of claim 13, wherein:
the first driver circuit comprises a first plurality of slice circuits configured to operate based on a first input data,
the second driver circuit includes a second plurality of slice circuits configured to operate based on a second input data,
the driver control circuit is configured to activate one or more of the first plurality of slice circuits during the first time period,
the driver control circuit is configured to activate one or more of the first plurality of slice circuits and one or more of the second plurality of slice circuits during the second time period.

15. The transmission driver of claim 14, wherein each of the first plurality of slice circuits comprises:
a first pulling circuit configured to operate based on a first input data; and
a variable common resistance circuit connected between the first pulling circuit and the first driver output node,
wherein the driver control circuit is configured to:
control a first resistance value corresponding to the variable common resistance circuit of each of slice circuits activated during the first time period among the first plurality of slice circuits to be smaller than a second resistance value corresponding to the variable common resistance circuit of each of slice circuits activated during the second time period among the first plurality of slice circuits.

16. The transmission driver of claim 15, wherein each of the second plurality of slice circuits comprises:
a second pulling circuit configured to operate based on the second input data; and
a constant common resistance circuit connected between the second pulling circuit and the second driver output node,
wherein a third resistance value corresponding to the constant common resistance circuit corresponds to the second resistance value.

17. The transmission driver of claim 14, wherein the driver control circuit is configured to:
determine whether to activate each of the first plurality of slice circuits based on a first plurality of slice activation signals, respectively;
determine whether to activate each of the second plurality of slice circuits based on a second plurality of slice activation signals, respectively; and
control, during the first time period, a first number of signals indicating activation among the first plurality of slice activation signals to be twice a second number of signals indicating activation among the second plurality of slice activation signals.

18. The transmission driver of claim 14, further comprising:
a third driver circuit including a third driver output node connected to a second channel output pad; and
a fourth driver circuit including a fourth driver output node connected to the second channel output pad,
wherein:
the driver control circuit is configured to further activate the third driver circuit during the first time period and further activate the fourth driver circuit during the second time period;
the fourth driver output node is configured to be electrically floated during the first time period;
the third driver circuit comprises a third plurality of slice circuits configured to operate based on a third input data complementary to the first input data,
the fourth driver circuit comprises a fourth plurality of slice circuits configured to operate based on a fourth input data complementary to the second input data.

19. A transmission driver, comprising:
a channel driver comprising a plurality of slice circuits; and
a driver control circuit configured to control the channel driver,
wherein the driver control circuit is configured to:
adjust a pull-up path resistance of the channel driver based on a number of activated slice circuits among the plurality of slice circuits; and
adjust a pull-down path resistance of the channel driver further based on a pull-down variable resistance circuit in each of the plurality of slice circuits.

20. The transmission driver of claim 19, wherein each of the plurality of slice circuits comprises:
a pull-up transistor, which is connected between a power node and a common node and configured to operate based on a voltage level of a driver input node;
a pull-down transistor, which is connected between the common node and a pull-down source node and configured to operate based on the voltage level of the driver input node;
the pull-down variable resistance circuit connected between the pull-down source node and a ground node; and
a slice activation transistor and a common resistor, which are connected in series between the common node and a channel output pad.
